(19) United States
(12) Patent Application Publication
(10) Pub. No.: US 2010/0243716 A1
(43) Pub. Date: Sep. 30, 2010

(54) Enhanced Connector Cradle Having a Cooling Shell for Preferential Cooling of Wafers

(75) Inventors: Joseph Kuczynski, Rochester, MN (US); Arvind K. Sinha, Rochester, MN (US); Kevin A. Splittstoesser, Stewartville, MN (US); Timothy J. Tofil, Rochester, MN (US)

Correspondence Address: IBM CORPORATION, 3605 HIGHWAY 52 NORTH, DEPT 917, ROCHESTER, MN, 55901-7829, US

(73) Assignee: INTERNATIONAL BUSINESS MACHINES CORPORATION, Armonk, NY (US)

(21) Appl. No.: 12/410,726

(22) Filed: Mar. 25, 2009

(51) Int. Cl. B23K 31/02; B23K 37/04; H01R 43/02; H05K 7/20

(52) U.S. Cl. 228/176; 228/44.7; 29/879; 165/80.4

(57) ABSTRACT

A method, system and apparatus for preferential cooling of an electrical circuit board via a cradle having a cooling shell. An enhanced connector cradle enables the secure and precise placement of a connector on a circuit board by using a cooling component which selectively enables only the connector leads to reach reflow temperature levels. The cradle aligns and securely connects the circuit board to the connector via a comb structure of the cradle to form a single connector unit. Heat is applied to the single connector unit to initiate bond formation. The cradle selectively minimizes the heat to the circuit board and other board components by enabling the circulation of de-ionized water through the cooling component during the heating process. As a result, the cradle restricts reflow temperature levels to the connector leads. The cradle mechanism is removed from the board after the connector is securely bonded to the board.

### BACKGROUND

1. Technical Field

The present invention generally relates to the coupling of a connector to an electrical circuit board, and in particular to a connector cradle for selectively cooling a wafer and circuit board when coupling a connector to the wafer.

2. Description of the Related Art

Large, high-density surface mount technology (SMT) connectors suffer from solder joint strain as a result of assembly and reflow process conditions. Lead mis-registration, solder joint cracking, hot tears, voids, and other defects may occur as a result of solder joint strain. A cradle is used for placement of the connector on a board while the cradle endures a heating process. Use of conventional cradles during the heating process produces large wafer deformation through solder reflow, resulting in high tensile forces on signal leads. There is presently no known solution to this problem.

In order to address the problems involving large wafer deformation and high tensile forces on signal leads, a number of mitigation efforts have been attempted, including new wafer designs, tightening of tolerances, and guide block underfill. However, none of these efforts address the large, inherent coefficient of thermal expansion (CTE) mismatch between the wafer, organizer, and the cradle.

### SUMMARY OF ILLUSTRATIVE EMBODIMENTS

Disclosed are a method, system and apparatus for preferential cooling of a circuit board via a cradle having a cooling shell. An enhanced connector cradle enables the secure and precise placement of a connector on an electrical circuit board by using a cooling component which selectively enables only the connector leads to reach reflow temperature levels. The cradle aligns and securely connects the circuit board to the connector via a comb structure of the cradle to form a single connector unit. Heat is applied to the single connector unit to initiate bond formation. The cradle selectively minimizes the heat to the circuit board and other board components by enabling the circulation of de-ionized water through the cooling component during the heating process. As a result, the cradle restricts reflow temperature levels to the connector leads. The cradle mechanism is removed from the board after the connector is securely bonded to the board.

The above as well as additional features and advantages of the present invention will become apparent in the following detailed written description.

### BRIEF DESCRIPTION OF THE DRAWINGS

The invention itself will best be understood by reference to the following detailed description of an illustrative embodiment when read in conjunction with the accompanying drawings, wherein:

FIG. 1 is a block diagram representation of an SMT cradle having a cooling shell, according to one embodiment;

FIG. 2A is a three dimensional (3-D) illustration of the SMT cradle with multiple circuit boards, according to one embodiment;

FIG. 2B is a section of the three dimensional (3-D) illustration of the SMT cradle with multiple circuit boards, according to one embodiment;

FIG. 3 is a table showing reduced solder joint stress using the cradle with the cooling shell, according to one embodiment of the invention; and

FIG. 4 is a flow chart showing the processes by which the features of the invention are implemented, according to one embodiment of the invention.

### DETAILED DESCRIPTION OF AN ILLUSTRATIVE EMBODIMENT

The illustrative embodiments provide a method, system and apparatus for preferential cooling of an electrical circuit board via a cradle having a cooling shell. An enhanced connector cradle enables the secure and precise placement of a connector on a circuit board by using a cooling component which selectively enables only the connector leads to reach reflow temperature levels. The cradle aligns and securely connects the circuit board to the connector via a comb structure of the cradle to form a single connector unit. Heat is applied to the single connector unit to initiate bond formation. The cradle selectively minimizes the heat to the circuit board and other board components by enabling the circulation of de-ionized water through the cooling component during the heating process. As a result, the cradle restricts reflow temperature levels to the connector leads. The cradle mechanism is removed from the board after the connector is securely bonded to the board.

In the following detailed description of exemplary embodiments of the invention, specific exemplary embodiments in which the invention may be practiced are described in sufficient detail to enable those skilled in the art to practice the invention, and it is to be understood that other embodiments may be utilized and that logical, architectural, programmatic, mechanical, electrical and other changes may be made without departing from the spirit or scope of the present invention. The following detailed description is, therefore, not to be taken in a limiting sense, and the scope of the present invention is defined only by the appended claims.

Within the descriptions of the figures, similar elements are provided similar names and reference numerals as those of the previous figure(s). Where a later figure utilizes the element in a different context or with different functionality, the element is provided a different leading numeral representative of the figure number. The specific numerals assigned to the elements are provided solely to aid in the description and not meant to imply any limitations (structural or functional) on the invention.

It is understood that the use of specific component, device and/or parameter names are for example only and not meant to imply any limitations on the invention. The invention may thus be implemented with different nomenclature/terminology utilized to describe the components/devices/parameters herein, without limitation. Each term utilized herein is to be given its broadest interpretation given the context in which that term is utilized.

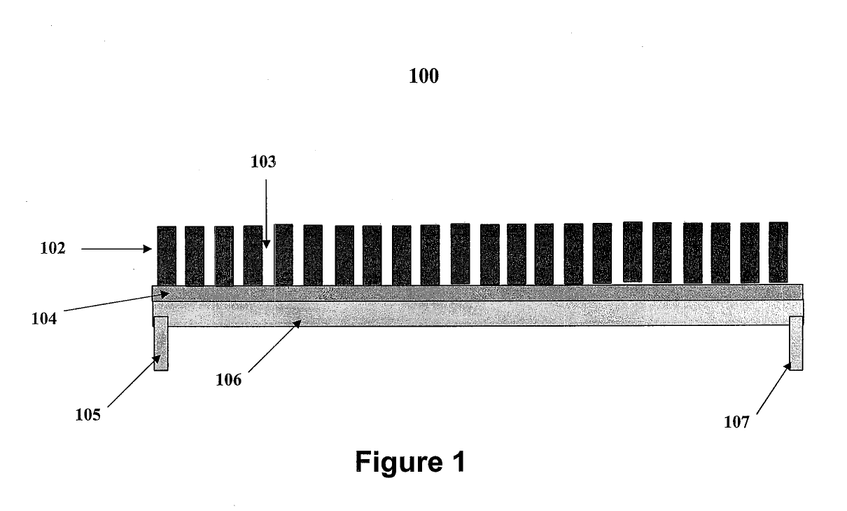

With reference now to the figures, FIG. 1 depicts a block diagram representation of an SMT cradle having a cooling shell, according to one embodiment. Cradle 100 comprises a comb structure 103 coupled to a top side of conductive interface 104. Comb structure 103 enables the alignment of circuit boards via slot(s) 103. Comb structure 103 is made of oxygen free copper to reduce reactions with components of circuit boards with which comb structure 103 may come into contact. Slot 103 is configured to hold a wafer/circuit board. Cooling shell 106 is coupled to the bottom side of conductive interface 104. Cooling shell 106 is hollow and has a first side and a second side. Inlet component 105 is coupled to the first side of cooling shell 106. Inlet component 105 is configured to receive liquid that flows to cooling shell 106 during a heating process. Outlet component 107 is coupled to the second side of cooling shell 106. Outlet component 107 is configured to release liquid from cooling shell 106 during the heating process. The flow of de-ionized water through cooling shell 106 during the heating process cools all of parts of the wafer/circuit board, except the SMT leads. The temperature gradient in the wafer/circuit board is minimized, reducing warp and stabilizing SMT joints. Solder defects are reduced and a solder bond is improved with nominal bond line thickness. The reflow process time is also reduced per connector.

In one embodiment, comb structure 103, conductive interface 104, and cooling shell 106 are made of highly conductive copper. During use, inlet component 105 is coupled to a hose configured to transport liquid, for example, de-ionized water, to inlet component 105 of cooling shell 106. The de-ionized water is transported from inlet component 105 to cooling shell 106 and released from outlet component 107 during the heating process. The de-ionized water released from outlet component 107 may be collected and re-circulated to inlet component 105. Once the heating process is complete, cradle 100 is removed.

Those of ordinary skill in the art will appreciate that the hardware depicted in FIG. 1 is a basic illustration of an SMT cradle having a cooling shell, and thus the hardware utilized in actual implementation may vary. Thus, the depicted example is not meant to imply architectural limitations with respect to the present invention. Also, components of cradle 100 may be distributed components, not present in a single device or single casing.

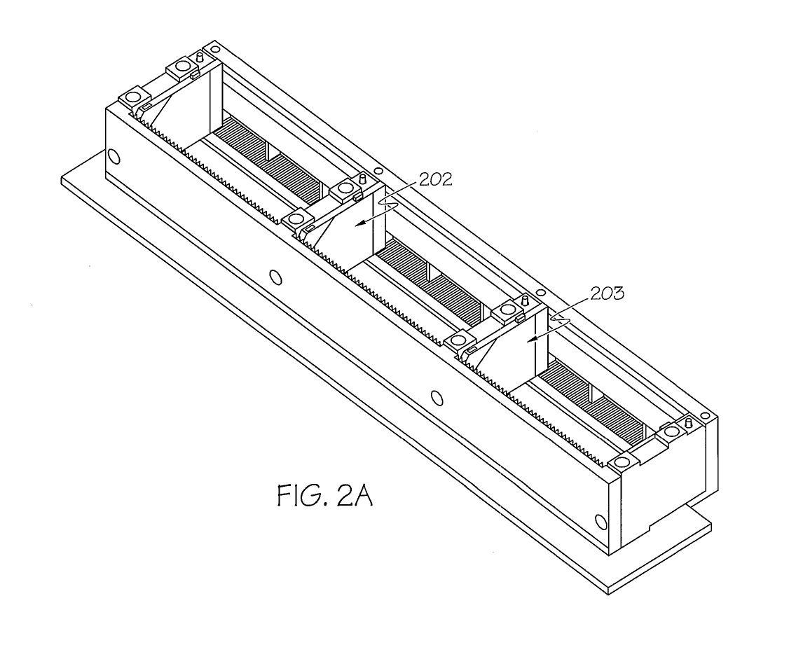

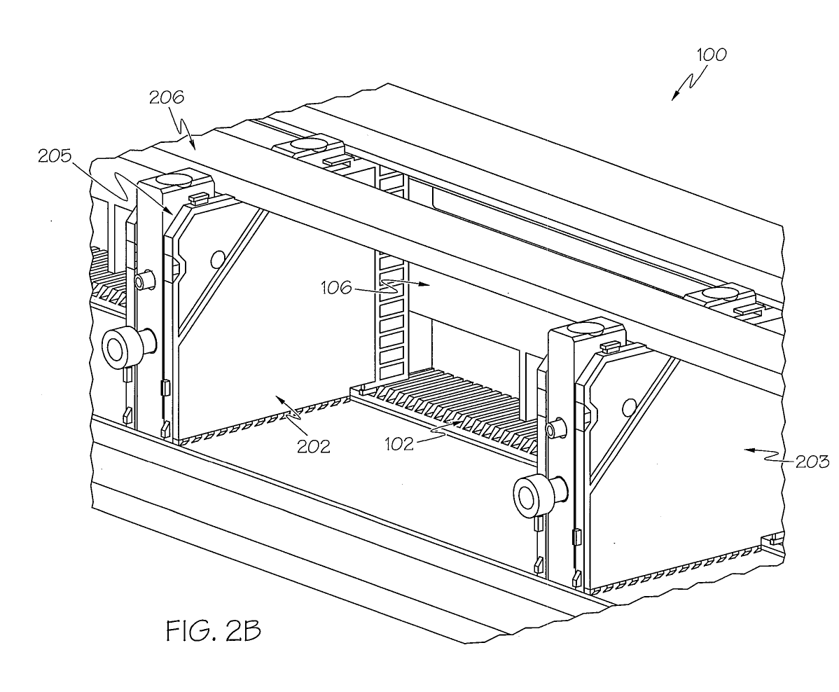

Among the mechanisms provided by cradle 100 which further enables features specific to the invention, are: (a) mechanisms for enabling the alignment of one or more wafers/circuit boards into a comb structure of a cradle having a cooling shell; (b) mechanisms for enabling secure connection of the wafers/circuit board to connectors and to the cradle to form a single connector unit; (c) mechanisms for enabling the application of heat to the single connector unit to allow solder reflow; and (d) mechanisms for cooling the single connector unit via a cooling shell contained within the cradle. According to the illustrative embodiment, cradle 100 having a cooling shell initiates a series of mechanisms, which are described below within the description of FIGS. 2-4.

With reference now to FIG. 2A, a three dimensional (3-D) representation of the SMT cradle with multiple circuit boards is illustrated, according to one embodiment. Cradle 100 comprises multiple circuit boards including first wafer/circuit board 202 and second wafer/circuit board 203. Further description of cradle 100 is facilitated with the magnified illustration of cradle 100 provided in FIG. 2B.

FIG. 2B depicts a section of the three dimensional (3-D) illustration of the SMT cradle with multiple circuit boards, according to one embodiment. Cradle 100 comprises multiple circuit boards including first wafer/circuit board 202 and second wafer/circuit board 203. Cradle 100 also comprises comb structure 102. In addition, cradle 100 comprises cooling shell/component 106. Securely fastening circuit board 202 to cradle 100 is clamp 205 and organizer 206. Additionally, cradle 100 encloses an SMT connector (not explicitly shown) which is bonded to circuit board 202 during a solder reflow process.

Surface-mount technology (SMT) is a method for constructing electronic circuits in which the components (SMC, or Surface Mounted Components) are mounted directly onto the surface of printed circuit boards (PCBs), e.g., first circuit board 202 and second circuit board 203. Electronic devices so made are called surface-mount devices or SMDs. SMT has largely replaced the through-hole technology construction method of fitting components with wire leads into holes in the circuit board. An SMT component is usually smaller than the through-hole counterpart because the SMT component has either smaller leads or no leads at all. The SMT component may have short pins or leads of various styles, flat contacts, a matrix of solder balls (e.g., ball grid arrays (BGAs)), or terminations on the body of the component. The location on circuit board 202, at which components are to be placed, has flat, usually tin-lead, silver, or gold plated copper pads without holes, called solder pads. Solder paste, a sticky mixture of flux and tiny solder particles, is first applied to all the solder pads with a stainless steel or nickel stencil using a screen printing process.

Cradle 100 forms a single connector unit by enclosing one or more SMT components while being securely connected to one or more circuit boards. In order to bond SMT components to circuit board 202, the heating process is initiated. In one embodiment, heat is applied to the single connector unit by passing the single connector unit through a reflow soldering oven. The single connection unit first enters a pre-heat zone, where the temperature of the boards and all the components is gradually, uniformly raised. The single connection unit then enters a zone where the temperature is high enough to melt the solder particles in the solder paste, bonding the SMT component leads to the pads on circuit board 202. During the heating process/phase, de-ionized water is circulated through cooling shell 106. The flow of de-ionized water through cooling shell 106 during the heating process cools all of the parts of circuit board 202, except SMT component leads. The temperature gradient in circuit board 202 is minimized, which reduces warp and stabilizes SMT joints. As a result, solder defects are reduced and a solder bond is improved using cradle 100.

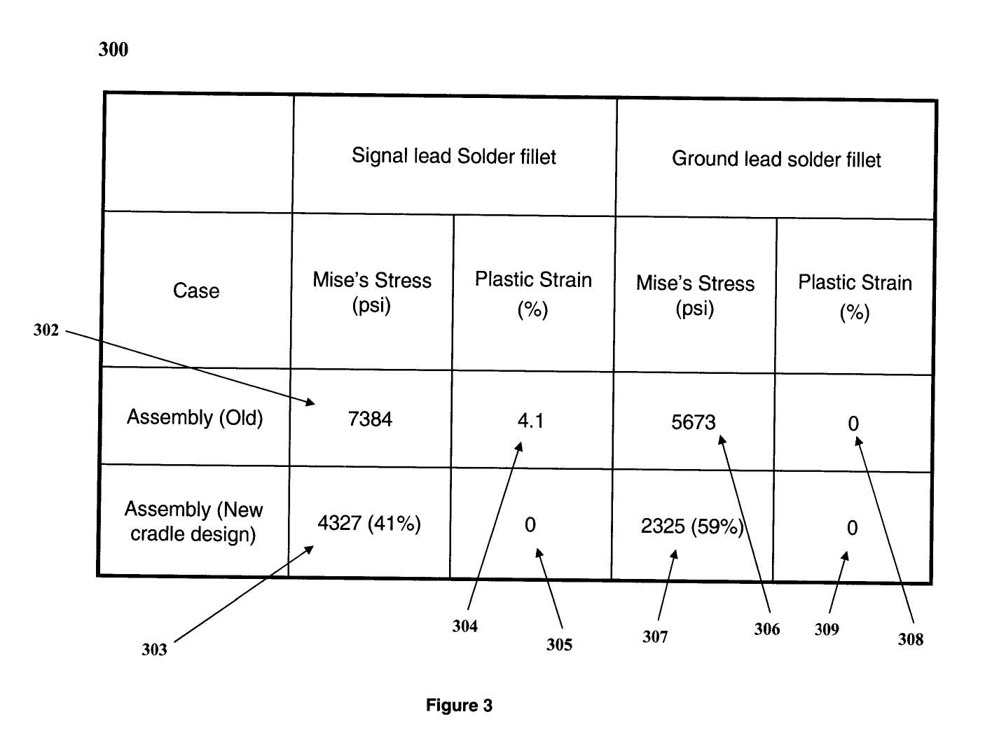

FIG. 3 is a table showing decrease in stresses at a solder joint when using the cradle with a cooling shell, according to one embodiment. In Table 300, the von Mise's stress applied to signal lead solder fillet and the plastic strain applied to signal lead solder fillet, both obtained when using a traditional cradle assembly, are compared with the corresponding values obtained when using the enhanced cradle with the cooling shell. Similarly, the von Mise's stress applied to ground lead solder fillet and the plastic strain applied to ground lead solder fillet, both obtained when using a traditional cradle assembly, are compared with the corresponding values obtained when using the enhanced cradle with the cooling shell.

According to table 300, the signal lead solder fillet undergoes a Mise's Stress of 7384 pounds per square inch (psi) as illustrated by first stress value 302 and a 4.1% plastic strain as illustrated by first strain value 304, when using a traditional cradle assembly 304. However, when using the enhanced cradle having cooling shell 106, the signal lead solder fillet is subjected to a Mise's Stress of 4327 psi as illustrated by second stress value 303 and 0% plastic strain as illustrated by second strain value 305. The von Mise's stress value of 4327 psi represents a 41% decrease in tensile forces for the signal lead solder fillet. The ground lead solder fillet undergoes a Mise's Stress of 5673 psi as illustrated by third stress value 306 and a 0% plastic strain as illustrated by third strain value 308, with the traditional assembly. When using the cradle with the cooling shell assembly, the ground lead solder fillet is subjected to a Mise's Stress of 2325 psi as illustrated by fourth stress value 307 and a 0% plastic strain as illustrated by fourth strain value 309. The von Mise's stress value of 2325 psi represents a 59% decrease in tensile force for the ground lead solder fillet. As illustrated, the cradle with the cooling shell provides significant improvement over the traditional assembly by reducing the stresses and strains for signal lead solder fillets and ground lead solder fillets. In addition, the enhanced cradle with the cooling shell produces no plastic strain which makes the enhanced cradle a viable design for reducing joint stresses on the leads.

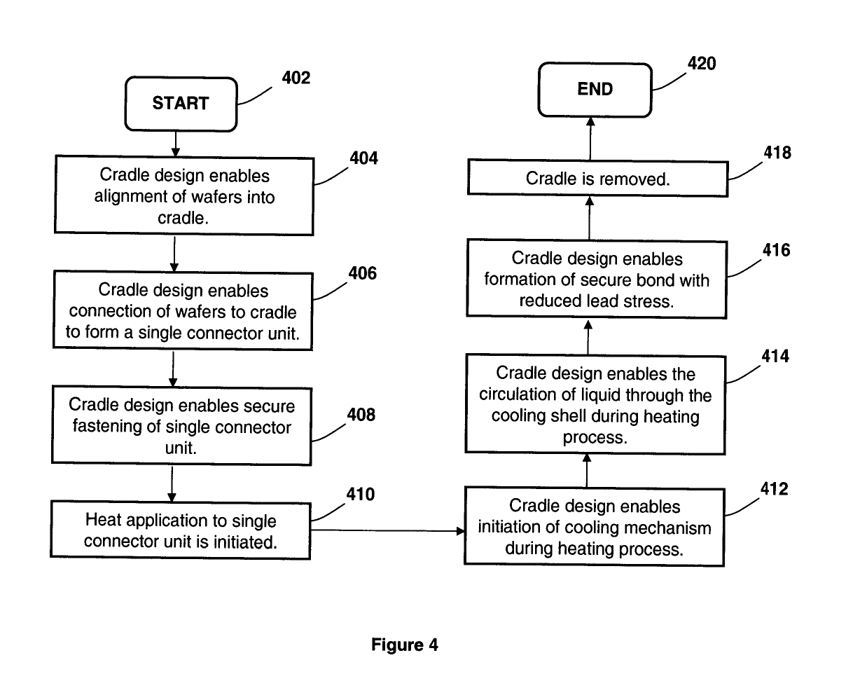

FIG. 4 is a flow chart illustrating one method by which the above process of the illustrative embodiments is completed. The process begins at initiator block 402, and proceeds to block 404 at which one or more wafers/circuit boards are aligned into a comb structure of cradle 100 which contains cooling shell 106. The wafers/circuit boards are connected to cradle 100 and one or more SMT connectors to form a single connector unit at block 406. At block 408, the single connector unit is secured via an organizer and a clamp. In one embodiment, a compression load is also applied to leads via a spring-loaded mechanism. Heat is applied to the single connector unit to initiate the formation of a bond between a circuit board and one or more leads, as shown at block 410.

At block 412, a cooling mechanism/process is initiated using cooling shell 106. A liquid (e.g., de-ionized water) is circulated through cooling shell 106 during the heating process, as shown at block 414. In one embodiment, the liquid is received into cooling shell 106 via an inlet component of cooling shell 106. The inlet component is connected to a hose to receive the liquid. Cooling shell 106 is made of highly conductive copper. The liquid released through the outlet component may be collected and re-circulated into the inlet component. At block 416, a secure bond with reduced lead and board stresses is formed. Cradle 100 is removed, as shown at block 418. The process ends at block 420.

In the flow chart above, the method may be embodied in an enhanced cradle having a cooling shell such that a series of steps are performed when using the cradle with the cooling shell to place a connector on a circuit board. In some implementations, certain steps of the method may be combined, performed simultaneously or in a different order, or perhaps omitted, without deviating from the spirit and scope of the invention. Thus, while the method steps are described and illustrated in a particular sequence, use of a specific sequence of steps is not meant to imply any limitations on the invention. Changes may be made with regards to the sequence of steps without departing from the spirit or scope of the present invention. Use of a particular sequence is therefore, not to be taken in a limiting sense, and the scope of the present invention is defined only by the appended claims.

While the invention has been described with reference to exemplary embodiments, it will be understood by those skilled in the art that various changes may be made and equivalents may be substituted for elements thereof without departing from the scope of the invention. In addition, many modifications may be made to adapt a particular system, device or component thereof to the teachings of the invention without departing from the essential scope thereof. Therefore, it is intended that the invention not be limited to the particular embodiments disclosed for carrying out this invention, but that the invention will include all embodiments falling within the scope of the appended claims. Moreover, the use of the terms first, second, etc. do not denote any order or importance, but rather the terms first, second, etc. are used to distinguish one element from another.

What is claimed is:

1. A system comprising:
a connector cradle having a comb structure with a conductive interface;
one or more alignment slots;
wherein an alignment slot is configured to hold a circuit board;
a cooling shell coupled to the conductive interface;
an inlet component coupled to a first side of the cooling shell, said inlet component configured to receive liquid that flows to the cooling shell during a heating process;
an outlet component coupled to a second side of the cooling shell, said outlet component configured to release liquid from the cooling shell during the heating process;
wherein the circuit board is connected to a connector and the connector cradle to form a single connector unit;
wherein said single connector unit enables a mechanism for creating a bond between the circuit board and one or more connector leads, wherein said mechanism for creating further comprises:
heating the single connector unit allowing solder reflow; and
cooling the single connector unit; and
when the bond is created, removing the connector cradle, spring-loaded mechanism, and clamp from the circuit board.

2. The system of claim 1, further comprising mechanisms for:
securing the single connector unit using one or more of: (a) an organizer; and (b) a clamp; and
applying compression load to connector leads via a spring-loaded mechanism.

3. The system of claim 1, wherein:
the conductive interface has a top side and a bottom side;
the one or more alignment slots extend from the top side of the conductive interface;
the cooling shell is coupled to the bottom side of the conductive interface; and
the comb, conductive interface, and cooling shell are made of highly conductive copper.

4. The system of claim 1, wherein the inlet component is coupled to a hose configured to transport liquid to the inlet component.

5. The system of claim 4, wherein the liquid is de-ionized water.

6. The system of claim 5, wherein the de-ionized water released from the outlet component of the cooling shell is collected and re-circulated into the inlet component.

7. The system of claim 6, wherein the connector cradle endures a heating of the connector unit, wherein said connector cradle is reusable following said heating of said connector unit.

8. A method, comprising:
aligning one or more circuit boards into a comb structure of a connector cradle having a cooling shell;
connecting the circuit boards to the connector cradle to form a single connector unit;
securing the single connector unit using one or more of: (a) an organizer; and (b) a clamp;
applying compression load to leads via a spring-loaded mechanism;
creating a bond between the circuit board and one or more leads, wherein said creating comprses:
heating the single connector unit allowing solder reflow; and
cooling the single connector unit; and
when the bond is created, removing the connector cradle, spring-loaded mechanism, and clamp from the circuit board.

9. The method of claim 8, further comprising cooling the single connector unit during the heating process by transporting liquid from an inlet component through the cooling shell of the connector cradle.

10. The method of claim 9, further comprising circulating the liquid through the cooling shell of the connector cradle to an outlet component during the heating process.

11. The method of claim 10, wherein the cooling shell is made of highly conductive copper.

12. The method of claim 11, wherein the liquid is de-ionized water.

13. The method of claim 12, further comprising collecting the released water from the outlet component and re-circulating the water into the inlet component.

14. The method of claim 13, further comprising reusing the connector cradle.

15. An apparatus, comprising:
a connector cradle having a comb structure with a conductive interface;
one or more alignment slots;
wherein an alignment slot is configured to hold a circuit board;
a cooling shell coupled to the conductive interface;
an inlet component coupled to a first side of the cooling shell, said inlet component configured to receive liquid that flows to the cooling shell during a heating process;
an outlet component coupled to a second side of the cooling shell, said outlet component configured to release liquid from the cooling shell during the heating process.

16. The apparatus of claim 15, wherein:
the conductive interface has a top side and a bottom side;
the one or more alignment slots extend from the top side of the conductive interface;
the cooling shell is coupled to the bottom side of the conductive interface; and
the comb, conductive interface, and cooling shell are made of highly conductive copper.

17. The apparatus of claim 15, wherein the inlet component is coupled to a hose configured to transport liquid to the inlet component of the cooling shell.

18. The apparatus of claim 17, wherein the liquid is de-ionized water.

19. The apparatus of claim 18, wherein the de-ionized water is transported from the inlet component to the cooling shell and released from the outlet component of the cooling shell.

20. The apparatus of claim 19, wherein the de-ionized water released from the outlet component is collected and re-circulated to the inlet component of the connector cradle.
